(19) United States
(12) Patent Application Publication
(10) Pub. No.: US 2026/0362885 A1
(43) Pub. Date: Nov. 12, 2026

(54) PIXEL UNIT

(71) Applicant: HUBEI SAN'AN OPTOELECTRONICS CO., LTD., Hubei (CN)

(72) Inventors: Weihong CHEN, Hubei (CN); Zhenduan LIN, Hubei (CN); Junpeng SHI, Hubei (CN); Zhiyang CENG, Hubei (CN); Ziyun SU, Hubei (CN); Jieling WANG, Hubei (CN); Changchin YU, Hubei (CN); Chenke HSU, Hubei (CN)

(21) Appl. No.: 19/721,535

(22) Filed: Jun. 26, 2026

Related U.S. Application Data
(63) Continuation-in-part of application No. PCT/CN2023/142428, filed on Dec. 27, 2023.

(51) Int. Cl. H10H 29/49

(52) U.S. Cl. CPC H10H 29/49

(57) ABSTRACT

A pixel unit includes light-emitting elements spaced apart from each other, and a wiring layer disposed on and electrically connected to the light-emitting elements. Each light-emitting element includes a semiconductor stacked structure including a first semiconductor layer, an active layer, and a second semiconductor layer, an insulating layer disposed on the semiconductor stacked structure and having openings that includes first and second openings, and electrode pads including first and second electrode pads. The first electrode pad is electrically connected to the first semiconductor layer through the first opening, and the second electrode pad is electrically connected to the second semiconductor layer through the second opening. Each electrode pad of each light-emitting element includes a contact region that extends into a respective one of the openings of the insulating layer, and the wiring unit is in partial contact with the contact region of each electrode pad of each light-emitting element.

### CROSS-REFERENCE TO RELATED APPLICATION

This application is a continuation-in-part (CIP) of International Application No. PCT/CN2023/142428, filed on Dec. 27, 2023, the entire disclosure of which is incorporated by reference herein.

### FIELD

The disclosure relates to semiconductor technology, and more particularly to a pixel unit and a display device.

### BACKGROUND

LED chips are widely used in displays, automotive lighting, and general illumination due to being reliable and having long lifespan and low power consumption. For example, an RGB LED chip may be used as a pixel unit in a display device. However, because micro-LED chips are exceptionally small (typically under 100 μm in size), transferring and mounting them individually onto display panels is highly difficult. To streamline this process, three RGB chips are combined into a single pixel package, making the mass-transfer and bonding process much easier.

Unfortunately, existing pixel packages suffer from poor reliability, and creating a highly reliable pixel unit remains a major challenge.

### SUMMARY

Therefore, an object of the disclosure is to provide a pixel unit that can alleviate at least one of the drawbacks of the prior art.

According to the disclosure, the pixel unit includes light-emitting elements that are spaced apart from each other, and a wiring unit that is disposed on and electrically connected to the light-emitting elements.

Each of the light-emitting elements includes a semiconductor stacked structure which includes a first semiconductor layer, an active layer, and a second semiconductor layer sequentially disposed in such order in a laminating direction, an insulating layer which is disposed on the semiconductor stacked structure and which has openings, the openings including a first opening and a second opening, and electrode pads which include a first electrode pad and a second electrode pad. The first electrode pad is electrically connected to the first semiconductor layer through the first opening, and the second electrode pad is electrically connected to the second semiconductor layer through the second opening. Each of the electrode pads of each of the light-emitting elements includes a contact region that extends into a respective one of the openings of the insulating layer, and the wiring unit is at least in partial contact with the contact region of each of the electrode pads of each of the light-emitting elements.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a schematic top view of a display device according to an embodiment of the present disclosure.

FIG. 2 is a schematic top view of a pixel unit according to an embodiment of the present disclosure.

FIG. 3 is a schematic cross-sectional view taken along line A-A′ of FIG. 2.

FIG. 4 is a partially enlarged schematic view of an area enclosed by the dashed-line box in FIG. 3.

FIG. 5 is a schematic top view of a light-emitting element according to an embodiment of the present disclosure.

FIG. 6 is a schematic cross-sectional view taken along line B-B′ of FIG. 5.

FIG. 7 is a schematic top view of the pixel unit according to another embodiment of the present disclosure.

FIG. 8 is a schematic top view of the pixel unit according to yet another embodiment of the present disclosure.

FIG. 9 is a schematic cross-sectional view taken along line C-C′ of FIG. 8.

FIG. 10 is a partially enlarged schematic view of FIG. 9.

FIG. 11 is a schematic view illustrating a filling layer according to an embodiment of the present disclosure.

FIG. 12 is a schematic view illustrating a wiring unit according to an embodiment of the present disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

It should be noted that the drawings provided in the present disclosure are merely schematic illustrations of the basic concepts of the present disclosure. The drawings depict only those components relevant to the present disclosure, and the number, shape, or dimensions, and proportions of the components may be varied as required, and the arrangement of the components may be more complex than that illustrated.

The structures, proportions, dimensions, and other features shown in the accompanying drawings are provided solely for the purpose of illustrating the contents disclosed in the specification, enabling persons skilled in the art to understand and practice the present disclosure, and are not intended to limit the scope or conditions under which the present disclosure may be implemented. Any modifications to the structures, changes in proportional relationships, or adjustments in size that do not depart from the effects achieved and the objectives attained by the present invention shall be deemed to fall within the scope of the technical disclosure of the present application.

A conventional pixel unit includes at least three light-emitting elements that are configured to emit red, green, and blue light, respectively. The conventional pixel unit includes a wiring layer that is in contact and electrically connected to electrode pads of the light-emitting elements, thereby redistributing circuit of the light-emitting elements. Such configuration eliminates a need for wire bonding, and effectively increases an area ratio of the light-emitting elements to the pixel unit. Furthermore, the redistributed circuit through the wiring layer decreases the number of the electrode pads required on the pixel unit, and the electrode pads are extended outward to areas in the pixel unit beyond the light-emitting elements, thereby leading to an increased individual pad size, which simplifies backend circuit design, makes backend surface mounting easier, and reduces an overall package size. However, in the present disclosure, each light-emitting element has a size that is smaller than 100 μm×100 μm, so openings in an insulating layer are relatively small compared to those in the light-emitting elements of the conventional pixel unit. Consequently, sidewalls that define the openings of the insulating layer are overly steep, so cracks are likely to be formed in the electrode pads at top edges of the sidewalls, thereby leading to poor electrical contact. When the wiring layer is in contact with the electrode pads that are cracked, risks of open or short circuits in a circuit of the pixel unit may be present.

In view of the above, the disclosure provides an embodiment of a pixel unit which includes light-emitting elements that are spaced apart from each other, and a wiring unit that is disposed on and electrically connected to the light-emitting elements. Each of the light-emitting elements includes a semiconductor stacked structure which includes a first semiconductor layer, an active layer, and a second semiconductor layer sequentially disposed in such order in a laminating direction, an insulating layer which is disposed on the semiconductor stacked structure and which has openings, the openings including a first opening and a second opening, and electrode pads which include a first electrode pad and a second electrode pad. The first electrode pad is electrically connected to the first semiconductor layer through the first opening, and the second electrode pad is electrically connected to the second semiconductor layer through the second opening. Each of the electrode pads of each of the light-emitting elements includes a contact region that extends into a respective one of the openings of the insulating layer, and the wiring unit is at least in partial contact with the contact region of each of the electrode pads of each of the light-Emitting elements.

In some embodiments, the pixel unit according to the disclosure further includes a transparent layer on which the light-emitting elements are disposed. For each of the light-emitting elements, the contact regions of the electrode pads includes a first contact region and a second contact region. The first electrode pad has the first contact region that extends into the first opening of the insulating layer, and the second electrode pad has the second contact region that extends into the second opening of the insulating layer.

In some embodiments, the pixel unit according to the disclosure further includes a filling layer that is disposed among the light-emitting elements. A surface of the filling layer away from the transparent layer is lower than a surface of each of the electrode pads of each of the light-emitting elements that is farthest away from the transparent layer, or the surface of the filling layer away from the transparent layer is higher than the surface of each of the electrode pads of each of the light-emitting element that is the farthest away from the transparent layer.

In some embodiments, the filling layer includes opening portions. At least one of the opening portions of the filling layer exposes the contact region of a corresponding one of the electrode pads.

In some embodiments, the wiring unit is in partial contact with the contact region of the corresponding one of the electrode pads through the at least one of the opening portions of the filling layer.

In some embodiments, an area of a projection of at least one of the opening portions of the filling layer on an imaginary plane perpendicular to the laminating direction is greater than an area of a projection of a corresponding one of the openings of the insulating layer of at least one of the light-emitting elements on the imaginary plane.

In some embodiments, a projection of at least one of the opening portions of the filling layer on the imaginary plane perpendicular to the laminating direction at least partially overlaps a projection of a corresponding one of the openings of the insulating layer of at least one of the light-emitting elements on the imaginary plane.

In some embodiments, the wiring unit includes a first wiring layer, a second wiring layer, a third wiring layer, and a fourth wiring layer. The light-emitting elements includes a first light-emitting element, a second light-emitting element, and a third light-emitting element. Each of the first light-emitting element, the second light-emitting element, and the third light-emitting element includes the first electrode pad and the second electrode pad. The first wiring layer is electrically connected to the first electrode pad of each of the first light-emitting element, the second light-emitting element, and the third light-emitting element. The second wiring layer is electrically connected to the second electrode pad of the first light-emitting element. The third wiring layer is electrically connected to the second electrode pad of the second light-emitting element. The fourth wiring layer is electrically connected to the second electrode pad of the third light-emitting element.

In some embodiments, the opening portions of the filling layer includes a first opening portion, a second opening portion, a third opening portion, a fourth opening portion, a fifth opening portion, and a sixth opening portion. The first opening portion at least partially exposes the first contact region of the first electrode pad of the first light-emitting element. The second opening portion at least partially exposes the second contact region of the second electrode pad of the first light-emitting element. The third opening portion at least partially exposes the first contact region of the first electrode pad of the second light-emitting element. The fourth opening portion at least partially exposes the second contact region of the second electrode pad of the second light-emitting element. The fifth opening portion at least partially exposes the first contact region of the first electrode pad of the third light-emitting element. The sixth opening portion at least partially exposes the second contact region of the second electrode pad of the third light-emitting element.

In some embodiments, the first wiring layer is in partial contact with the first contact region of the first electrode pad of each of the first light-emitting element, the second light-emitting element, and the third light-emitting element through the first opening portion, the third opening portion, and the fifth opening portion of the filling layer, respectively. The second wiring layer is in partial contact with the second contact region of the second electrode pad of the first light-emitting element through the second opening portion of the filling layer. The third wiring layer is in partial contact with the second contact region of the second electrode pad of the second light-emitting element through the fourth opening portion of the filling layer. The fourth wiring layer is in partial contact with the second contact region of the second electrode pad of the third light-emitting element through the sixth opening portion of the filling layer.

In some embodiments, each of the opening portions of the filling layer has an elliptical shape or a circular shape.

In some embodiments, the surface of each of the electrode pads of the light-emitting elements is free of the filling layer.

In some embodiments, a projection of the contact region of at least one of the electrode pads of at least one of the light-emitting elements on the imaginary plane perpendicular to the laminating direction partially overlaps a projection of the wiring unit on the imaginary plane.

In some embodiments, a projection of the contact region of at least one of the electrode pads of at least one of the light-emitting elements on the imaginary plane perpendicular to the laminating direction falls within a projection of the wiring unit on the imaginary plane.

In some embodiments, a projection of at least one of the electrode pads of the light-emitting elements on the imaginary plane perpendicular to the laminating direction falls within a projection of the wiring unit on the imaginary plane.

In some embodiments, an entirety of the contact region of each of the electrode pads of each of the light-emitting elements is in contact with the wiring unit.

In some embodiments, a minimum distance is formed between the first wiring layer and the second wiring layer, a minimum distance is formed between the first wiring layer and the third wiring layer, and a minimum distance is formed between the first wiring layer and the fourth wiring layer. Each of the minimum distances ranges from 1 μm to 50 μm.

In some embodiments, a minimum width of the wiring unit ranges from 1 μm to 50 μm.

In some embodiments, a contact area between the wiring unit and the contact region of each of the electrode pads of each of the light-emitting elements occupies at least 50% of a total area of the contact region of each of the electrode pads of each of the light-emitting elements.

According to another aspect of the present disclosure, a display device is provided and includes a panel substrate and pixel modules that are disposed on the panel substrate. Each of the pixel modules includes the pixel unit as described previously. The display device includes the pixel unit, and thus has superior display and reliability.

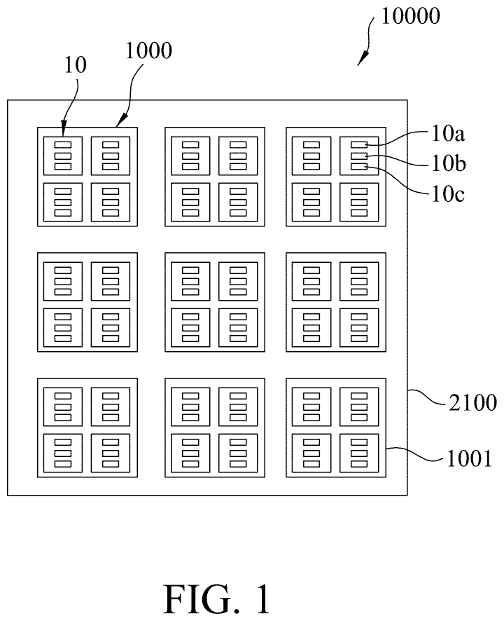

Referring to FIG. 1, a display device 10000 according to the present disclosure is shown.

The display device 10000 may include a panel substrate 2100 and pixel modules 1000.

The display device 10000 is not particularly limited and may include a micro LED TV, a smart watch, a VR display device such as a VR head-mounted device, or an AR display device such as augmented reality glasses.

The panel substrate 2100 may include a circuit for passive matrix driving or active matrix driving. In one embodiment, the panel substrate 2100 includes wiring and resistors, and in another embodiment, the panel substrate 2100 includes wiring, transistors and capacitors. The panel substrate 2100 may also have connecting pads on an upper surface thereof that may be electrically connected to an arranged circuit.

In one embodiment, the pixel modules 1000 are neatly disposed on the panel substrate 2100. Each of the pixel modules 1000 may include a circuit substrate 1001 and pixel units 10 that are disposed on the circuit substrate 1001. In another embodiment, the pixel units 10 may also be directly disposed on the panel substrate 2100.

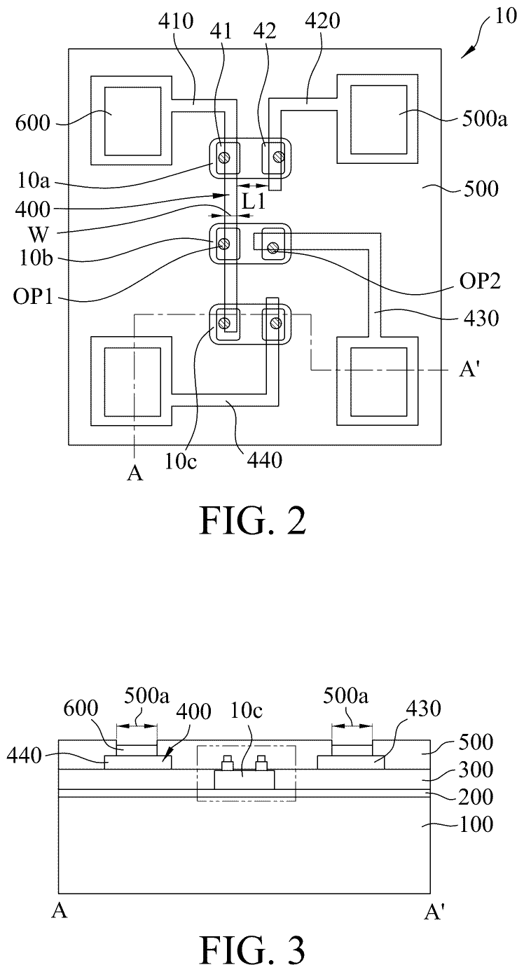

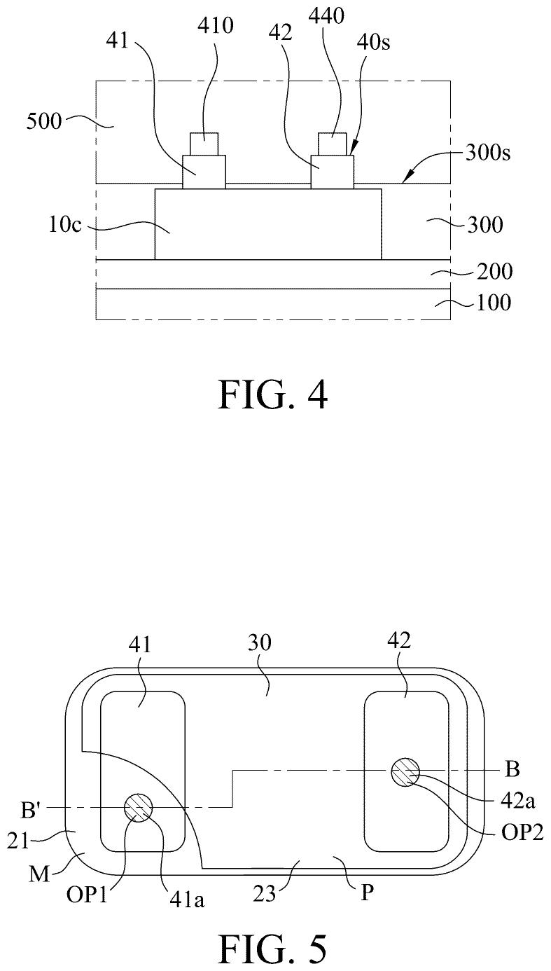

FIG. 2 is a schematic top view of a pixel unit 10 according to an embodiment of the present disclosure, FIG. 3 is a schematic cross-sectional view taken along line A-A′ of FIG. 2, and FIG. 4 is a partially enlarged schematic view of FIG. 3.

As shown in FIGS. 2 and 3, the pixel unit 10 includes a transparent layer 100 on which light-emitting elements are disposed spaced apart from each other, a filling layer 300 that is disposed among the light-emitting elements, a wiring unit 400 that is disposed on and electrically connected to the light-emitting elements, and a passivation layer 500 that is disposed on the wiring unit 400.

The transparent layer 100 may have a light transmittance of more than 60% in the visible light range. In some embodiments, the transparent layer 100 may be a transparent substrate that may be a light-transmitting substrate made of polyethylene terephthalate (PET), glass, quartz, sapphire, transparent ceramic, etc. The pixel unit 10 requires a certain thickness for optimal use, so in certain embodiments, a thickness of the transparent layer 100 is greater than 10 μm. Specifically, the thickness of the transparent layer 100 may range from 30 μm to 50 μm, from 50 μm to 100 μm, from 100 μm to 150 μm, or from 150 μm to 300 μm. The light-emitting elements are disposed on a surface of the transparent layer 100. Another surface of the transparent layer 100 away from the surface on which the light-emitting elements are disposed is a light-emitting surface of the pixel unit 10. That is to say, light emitted by the light-emitting elements is emitted outward through the transparent layer 100.

The light-emitting elements includes a first light-emitting element 10a, a second light-emitting element 10b, and a third light-emitting element 10c. The first, second and third light-emitting elements 10a, 10b, 10c may each emit different colors of light. The first, second and third light-emitting elements 10a, 10b, 10c in each pixel unit 10 may be arranged in a column as shown in FIG. 1. In one embodiment, the first, second and third light-emitting elements 10a, 10b, 10c may be arranged in a vertical direction relative to a display screen that is for realizing an image. However, the present disclosure is not limited thereto, and the first, second and third light-emitting elements 10a, 10b, 10c may also be arranged in a horizontal direction relative to the display screen that is for realizing an image.

In some embodiments, the light-emitting elements (e.g., the first, second and third light-emitting elements 10a, 10b, 10c) may be micrometer-level light-emitting diodes. A width and a length of each of the micrometer-level light-emitting diodes may range from 2 μm to 5 μm, from 5 μm to 10 μm, from 10 μm to 20 μm, from 20 μm to 50 μm, or from 50 μm to 100 μm . A thickness of each of the micrometer-level light-emitting diodes may range from 2 μm to 15 μm or from 5 μm to 10 μm. Each of the light-emitting elements further includes a first electrode pad 41 and a second electrode pad 42.

Referring to FIG. 3, the filling layer 300 fills gaps among the light-emitting elements, or is formed around a sidewall of each of the light-emitting elements so as to electrically isolate the light-emitting elements from each other and to prevent color mixing or light interference thereamong, thereby improving color contrast of the pixel unit 10. The filling layer 300 may be a black glue layer that absorbs light.

Since the thickness of each of the light-emitting elements ranges from 2 μm to 15 μm, and a distance between adjacent ones of the light-emitting elements is smaller than 50 μm, a material with good fluidity may be used for forming the filling layer 300 and is solidified after filling. The filling layer 300 may have a black filling component, and a particle size of the black filling component may be no greater than a tenth of the thickness of each of the light-emitting elements, thereby preventing the filling layer 300 from having a poor covering effect on the light-emitting elements due to an excessive particle size of the black filling component, which may in turn affect the color contrast of the pixel unit 10. The filling layer 300 may include a transparent or translucent material, and the black filling component with a particle size of not greater than 1 μm is dispersed in the transparent or translucent material. The transparent or translucent material may include silica gel, epoxy resin, polyimide, low-temperature glass, polysiloxane, polysilazane, etc. The black filling component of the filling layer 300 may include, but is not limited to, carbon black, titanium nitride, iron oxide (e.g., FeO, Fe₃O₄), iron powder, etc. The particle size of the black filling component may range from 10 nm to 100 nm, from 100 nm to 200 nm, from 200 nm to 300 nm, or from 300 nm to 500 nm. The filling layer 300 may also be black dye.

To prevent color mixing or light interference among the light-emitting elements, the filling layer 300 covers at least an active layer of each of the light-emitting elements, and may entirely cover the sidewall of each of the light-emitting elements. In an alternative embodiment, a thickness of the filling layer 300 is greater than the thickness of each of the light-emitting elements, which prevents light interference caused by light leakage from a bottom of each of the light-emitting elements. The thickness of the filling layer 300 may be smaller than 15 μm.

In one embodiment, referring to FIG. 4 with the third light-emitting element 10c being an example, a surface 300s of the filling layer 300 away from the transparent layer 100 is lower than a surface 40s of each of the electrode pads (i.e., the first and second electrode pads 41, 42) of the third light-emitting element 10c that is farthest away from the transparent layer 100. In other words, the filling layer 300 only covers the sidewalls of the light-emitting elements, and the surface 40s of each of the first electrode pad 41 and the second electrode pad 42 of the third light-emitting element 10c is free of the filling layer 300.

Referring again to FIG. 2 and FIG. 3, the wiring unit 400 is disposed on the light-emitting elements and the filling layer 300, and is in contact with the first and second electrode pads 41, 42 of each of the light-emitting elements.

The wiring unit 400 may include wiring layers. In one embodiment, as shown in FIG. 2, the wiring layers of the wiring unit 400 include a first wiring layer 410, a second wiring layer 420, a third wiring layer 430, and a fourth wiring layer 440. The first wiring layer 410 serves as a common wiring layer to electrically connect the first electrode pads 41 of the first light-emitting element 10a, the second light-emitting element 10b, and the third light-emitting element 10c in series. The second electrode pad 42 of the first light-emitting element 10a is connected to the second wiring layer 420, the second electrode pad 42 of the second light-emitting element 10b is connected to the third wiring layer 430, and the second electrode pad 42 of the third light-emitting element 10c is connected to the fourth wiring layer 440.

Alternatively, the first wiring layer 410 serves as a common wiring layer to electrically connect the second electrode pads 42 of the first light-emitting element 10a, the second light-emitting element 10b and the third light-emitting element 10c in series. The first electrode pad 41 of the first light-emitting element 10a is connected to the second wiring layer 420, the first electrode pad 41 of the second light-emitting element 10b is connected to the third wiring layer 430, and the first electrode pad 41 of the third light-emitting element 10c is connected to the fourth wiring layer 440.

The wiring unit 400 may have a single-layer structure or a multilayered structure, and may be made of at least one material that includes titanium, copper, chromium, nickel, gold, platinum, aluminum, titanium nitride, tantalum nitride or tantalum by methods such as sputtering, evaporation or the like. In this embodiment, the wiring unit 400 is a composite metal layer formed by Ti and Cu, and a thickness of the wiring unit 400 ranges from 50 nm to 1000 nm (e.g., 100 nm, 200 nm, 500 nm, 600 nm, 800 nm, etc.). The material of the wiring unit 400 may ensure a good adhesion between the wiring unit 400 and the filling layer 300, and the thickness thereof may ensure a good electrical connection with the light-emitting elements.

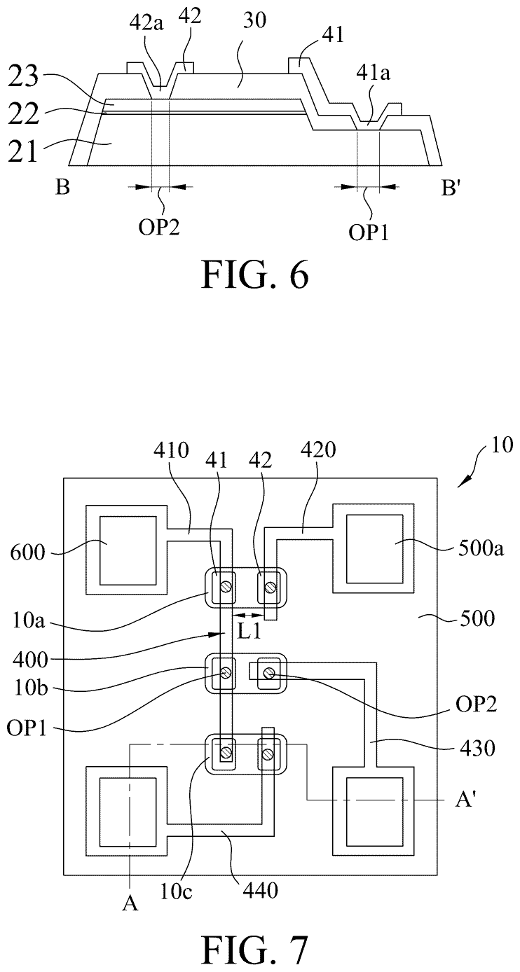

FIG. 5 is a schematic top view of the first light-emitting element 10a according to an embodiment of the present disclosure, and FIG. 6 is a schematic cross-sectional view taken along line B-B′ of FIG. 5. The first light-emitting element 10a is used as an example for description purposes herein, and since the second and third light-emitting elements 10b, 10c may also have substantially similar structures, repeated descriptions thereof will be omitted.

As shown in FIG. 6, the first light-emitting element 10a includes a semiconductor stacked structure which includes a first semiconductor layer 21, an active layer 22 and a second semiconductor layer 23 sequentially disposed in such order in a laminating direction, an insulating layer 30 which is disposed on the semiconductor stacked structure, and the first electrode pad 41 and the second electrode pad 42 which are disposed on the insulating layer 30.

When being viewed from above the first light-emitting element 10a, the first light-emitting element 10a may have a rectangular shape having a long side and a short side. For example, the long side may be smaller than 100 μm in length, and the short side may be smaller than 70 μm in length. The first, second, and third light-emitting elements 10a, 10b, and 10c may have substantially similar shapes and sizes.

The semiconductor stacked structure (i.e., the first semiconductor layer 21, the active layer 22, and the second semiconductor layer 23) may be grown on a growth substrate. The growth substrate may be a gallium nitride (GaN) substrate, a gallium arsenide (GaAs) substrate, a silicon (Si) substrate, or a sapphire substrate. In some embodiments, a patterned sapphire substrate may be used as the growth substrate. The growth substrate may be separated from the semiconductor stacked structure by mechanical grinding, laser lift-off, chemical lift-off, and the like. However, the present disclosure is not limited thereto, and a portion of the growth substrate may also remain to constitute at least a portion of the first semiconductor layer 21.

The first semiconductor layer 21 and the second semiconductor layer 23 are opposite in polarities. When the first semiconductor layer 21 is n-type, the second semiconductor layer 23 is p-type, and when the first semiconductor layer 21 is p-type, the second semiconductor layer 23 is n-type.

The first semiconductor layer 21, the active layer 22, and the second semiconductor layer 23 may be grown on the growth substrate using well-known methods such as metal-organic chemical vapor deposition (MOCVD). In addition, the first semiconductor layer 21 may include an n-type impurity (e.g., Si, Ge, Sn), and the second semiconductor layer 23 may include a p-type impurity (e.g., Mg, Sr, Ba). In one embodiment, the first semiconductor layer 21 may include GaN or AlGaN doped with Si, and the second semiconductor layer 23 may include GaN or AlGaN doped with Mg.

Although the first semiconductor layer 21 and the second semiconductor layer 23 are shown as having single-layer structures in the figures, the first semiconductor layer 21 and the second semiconductor layer 23 may each be a multilayered structure and may also include a superlattice structure. The active layer 22 may include a single quantum well structure or a multi-quantum well structure, and an element ratio of a nitride-based semiconductor may be adjusted to emit light with a desired wavelength. For example, the active layer 22 may emit blue light, green light, red light or ultraviolet light.

The semiconductor stacked structure may be patterned using photolithography, etching, etc. so as to have a semiconductor platform (P) and a mesa (M). The mesa (M) is formed by removing a portion of the second semiconductor layer 23 and a portion of the active layer 22 to expose a portion of an upper surface of the first semiconductor layer 21. The semiconductor platform (P) is a structure that generally includes the first semiconductor layer 21, the active layer 22, and the second semiconductor layer 23.

As shown in FIG. 6, the first semiconductor layer 21 of the first light-emitting element 10a may have an inclined side surface. The inclined side surface of the first semiconductor layer 21 may be formed by an isolation trench formation process. An inclination angle of the inclined side surface of the first semiconductor layer 21 relative to a lower surface of the first semiconductor layer 21 may range from about 40 degrees to about 80 degrees. The semiconductor platform (P) may also have an inclined side surface, and an inclination angle of the semiconductor platform (P) relative to a lower surface of the semiconductor platform (P) may range from about 40 degrees to about 80 degrees. Since both of the first semiconductor layer 21 and the semiconductor platform (P) have the inclined side surfaces, the insulating layer 30 (to be described later) may be formed thereon more easily.

The insulating layer 30 is disposed on and covers the semiconductor stacked structure, and includes a first opening (OP1) and a second opening (OP2). The insulating layer 30 may include a distributed Bragg reflector that has sub-insulating layers each having a different refractive index. For example, the distributed Bragg reflector may include at least two sub-insulating layers selected from SiO₂, Si₃N₄, SiON, TiO₂, Ta₂O₅, Nb₂O₅, MgF₂, etc. The distributed Bragg reflector may include, for example, multiple pairs of sub-insulating layers, each pair including a low-refractive-index layer and a high-refractive-index layer. The distributed Bragg reflector may include, for example, more than 10 pairs of the sub-insulating layers.

The distributed Bragg reflector reflects light emitted from the active layer 22. The distributed Bragg reflector may exhibit high reflectivity over a relatively wide wavelength range including a peak wavelength of the light emitted from the active layer 22, and may be designed in consideration of an incident angle of the light. In one embodiment, the distributed Bragg reflector may have a higher reflectivity for light incident at an incident angle of 0 degrees than for light incident at other incident angles. In another embodiment, the distributed Bragg reflector may have a higher reflectivity for light incident at other specific incident angles than for light incident at an incident angle of 0 degrees. For example, the distributed Bragg reflector may have a higher reflectivity for light incident at an incident angle of 10 degrees than for light incident at an incident angle of 0 degrees.

The first electrode pad 41 and the second electrode pad 42 are disposed on the insulating layer 30. The first electrode pad 41 may be electrically connected to the first semiconductor layer 21 through the first opening (OP1), and the second electrode pad 42 may be electrically connected to the second semiconductor layer 23 through the second opening (OP2).

In one embodiment, referring to FIG. 5, each of the first and second electrode pads 41, 42 includes a contact region that extends into a respective one of the first and second openings (OP1, OP2) of the insulating layer 30. In some embodiments, the contact regions include a first contact region 41a and a second contact region 42a. The first electrode pad 41 has the first contact region 41a that extends into the first opening (OP1) of the insulating layer 30, and the first electrode pad 41 is electrically connected to the first semiconductor layer 21 of the first light-emitting element 10a through the first contact region 41a. The second electrode pad 42 has the second contact region 42a that extends into the second opening (OP2) of the insulating layer 30, and the second electrode pad 42 is electrically connected to the second semiconductor layer 23 of the first light-emitting element 10a through the second contact region 42a. A projection of the first contact region 41a on an imaginary plane perpendicular to the laminating direction overlaps a projection of the first opening (OP1) on the imaginary plane. A projection of the second contact region 42a on the imaginary plane overlaps a projection of the second opening (OP2) on the imaginary plane.

Each of the first electrode pad 41 and the second electrode pad 42 may have a single-layer structure or a multilayered structure that is made of a metallic material, such as Al, Ti, Cr, Ni, Au, or alloys thereof.

Since a size of each of the light-emitting elements according to the present disclosure is smaller than 100 μm×100 μm, sizes of the first opening (OP1) and the second opening (OP2) of the insulating layer 30 are comparatively smaller than openings of an insulating layer of a conventional light-emitting element, thereby resulting in steeper sidewalls that define the first opening (OP1) and the second opening (OP2). In addition, a thickness of each of the first electrode pad 41 and the second electrode pad 42 of each of the light-emitting elements ranges from only 1 μm to 2 μm, thereby being unable to effectively cover the steep sidewalls that define the first opening (OP1) and the second opening (OP2) of the insulating layer 30, so cracks are likely to form in the first electrode pad 41 at a top edge of the sidewall that defines the first opening (OP1) and in the second electrode pad 42 at a top edge of the sidewall that defines the second opening (OP2), which leads to poor electrical contact.

As shown in FIGS. 2 to 4, using the third light-emitting element 10c as an example, the surfaces 40s of the first and second electrode pads 41, 42 are not covered by the filling layer 300, and the wiring unit 400 is at least in partial contact with the contact regions of the first and second electrode pads 41, 42, which not only enables the wiring unit 400 to be electrically connected to the third light-emitting element 10c, but also prevents poor electrical contact between the wiring unit 400 and the third light-emitting element 10c caused by cracks formed in the first and second electrode pads 41, 42 at the top edges of the sidewalls of the insulating layer 30 that define the first and second openings (OP1, OP2), thereby improving reliability of the pixel unit 10. In the event of poor electrical connection occurring at the first contact region 41a of the first electrode pad 41 in the first opening (OP1) of the insulating layer 30 and at the second contact region 42a of the second electrode pad 42 in the second opening (OP2) of the insulating layer 30, electrical connection is instead established between the wiring unit 400 and regions of the first and second electrode pads 41, 42 outside the first and second contact regions 41a, 42a, consequently the pixel unit 10 may experience undesired open or short-circuits. In an embodiment, a contact area between the wiring unit 400 and the contact region of each of the first and second electrode pads 41, 42 of each light-emitting element occupies at least 50% of a total area of the contact region of each of the first and second electrode pads 41, 42 of each light-emitting element.

In one embodiment, the first wiring layer 410 serves as a common wiring layer, and the first electrode pad 41 of each of the first light-emitting element 10a, the second light-emitting element 10b, and the third light-emitting element 10c is electrically connected to the first wiring layer 410. A projection of the first wiring layer 410 on the imaginary plane at least partially overlaps the first electrode pad 41 of the first light-emitting element 10a, the first electrode pad 41 of the second light-emitting element 10b, or the first electrode pad 41 of the third light-emitting element 10c. Since the first and second electrode pads 41, 42 of each of the first, second, and third light-emitting elements 10a, 10b, 10c are not covered by the filling layer 300, an overlapping area of the projection of the first wiring layer 410 on the imaginary plane and the first electrode pad 41 of the first light-emitting element 10a, the first electrode pad 41 of the second light-emitting element 10b, or the first electrode pad 41 of the third light-emitting element 10c is the first contact region 41a. To prevent cracks from forming in the first electrode pad 41 of the first light-emitting element 10a, the first electrode pad 41 of the second light-emitting element 10b, or the first electrode pad 41 of the third light-emitting element 10c at the top edge of the sidewall that defines a corresponding first opening (OP1) of the insulating layer 30, which may lead to poor electrical contact between the wiring unit 400 and one of the first, second and third light-emitting elements 10a, 10b, 10c, the first wiring layer 410 is at least in partial contact with the first contact region 41a of the first electrode pad 41 of the first, second or third light-emitting element 10a, 10b, 10c. Such design not only allows the first wiring layer 410 to be electrically connected to the first light-emitting element 10a, the second light-emitting element 10b or the third light-emitting element 10c, but also prevents poor electrical contact between the first wiring layer 410 and one of the first, second, and third light-emitting elements 10a, 10b, 10c caused by cracks formed in the first electrode pad 41 of the first, second, or third light-emitting element 10a, 10b, 10c at the top edge of the sidewall that defines a corresponding first opening (OP1) of the insulating layer 30.

FIG. 7 is a schematic top view of the pixel unit 10 according to another embodiment of the present disclosure. In the embodiment, as shown in FIG. 7, a projection of the first contact region 41a of the first electrode pad 41 of each of the first, second, and third light-emitting elements 10a, 10b, 10c on the imaginary plane falls within the projection of the first wiring layer 410 on the imaginary plane. That is to say, an entirety of the first contact region 41a of the first electrode pad 41 of each of the first, second, and third light-emitting elements 10a, 10b, 10c is in contact with the first wiring layer 410.

In another embodiment, not shown in the figures, a projection of the first electrode pad 41 of each of the first, second, and third light-emitting elements 10a, 10b, 10c on the imaginary plane falls within the projection of the first wiring layer 410 on the imaginary plane. That is to say, an entirety of the first electrode pad 41 of each of the first, second, and third light-emitting elements 10a, 10b, 10c is in contact with the first wiring layer 410.

In one embodiment, referring to FIG. 2 again, the second wiring layer 420 is electrically connected to the second electrode pad 42 of the first light-emitting element 10a. A projection of the second wiring layer 420 on the imaginary plane at least partially overlaps a projection of the second contact region 42a of the second electrode pad 42 of the first light-emitting element 10a on the imaginary plane. In an embodiment, the projection of the second contact region 42a of the second electrode pad 42 of the first light-emitting element 10a on the imaginary plane falls within the projection of the second wiring layer 420 on the imaginary plane. That is to say, an entirety of the second contact region 42a of the second electrode pad 42 of the first light-emitting element 10a is in contact with the second wiring layer 420. In another embodiment, a projection of the second electrode pad 42 of the first light-emitting element 10a on the imaginary plane falls within the projection of the second wiring layer 420 on the imaginary plane. That is to say, an entirety of the second electrode pad 42 of the first light-emitting element 10a is in contact with the second wiring layer 420. Such design not only allows the second wiring layer 420 to be electrically connected to the first light-emitting element 10a, but also prevents poor electrical contact between the second wiring layer 420 and the first light-emitting element 10a caused by cracks formed in the second electrode pad 42 of the first light-emitting element 10a at the top edge of the sidewall that defines the corresponding second opening (OP2) of the insulating layer 30.

Similarly, in one embodiment, the third wiring layer 430 is electrically connected to the second electrode pad 42 of the second light-emitting element 10b. A projection of the third wiring layer 430 on the imaginary plane at least partially overlaps the projection of the second contact region 42a of the second electrode pad 42 of the second light-emitting element 10b on the imaginary plane. In an embodiment, the projection of the second contact region 42a of the second electrode pad 42 of the second light-emitting element 10b on the imaginary plane falls within the projection of the third wiring layer 430 on the imaginary plane. That is to say, an entirety of the second contact region 42a of the second electrode pad 42 of the second light-emitting element 10b is in contact with the third wiring layer 430. In another embodiment, a projection of the second electrode pad 42 of the second light-emitting element 10b on the imaginary plane falls within the projection of the third wiring layer 430 on the imaginary plane. That is to say, an entirety of the second electrode pad 42 of the second light-emitting element 10b is in contact the third wiring layer 430. Such design not only allows the third wiring layer 430 to be electrically connected to the second light-emitting element 10b, but also prevents poor electrical contact between the third wiring layer 430 and the second light-emitting element 10b caused by cracks formed in the second electrode pad 42 of the second light-emitting element 10b at the top edge of the sidewall that defines the corresponding second opening (OP2) of the insulating layer 30.

In one embodiment, the fourth wiring layer 440 is electrically connected to the second electrode pad 42 of the third light-emitting element 10c. A projection of the fourth wiring layer 440 on the imaginary plane at least partially overlaps a projection of the second contact region 42a of the second electrode pad 42 of the third light-emitting element 10c on the imaginary plane. In an embodiment, the projection of the second contact region 42a of the second electrode pad 42 of the third light-emitting element 10c on the imaginary plane falls within the projection of the fourth wiring layer 440 on the imaginary plane. That is to say, an entirety of the second contact region 42a of the second electrode pad 42 of the third light-emitting element 10c is in contact with the fourth wiring layer 440. In another embodiment, the projection of the second electrode pad 42 of the third light-emitting element 10c on the imaginary plane falls within the projection of the fourth wiring layer 440 on the imaginary plane. That is to say, an entirety of the second electrode pad 42 of the third light-emitting element 10c is in contact with the fourth wiring layer 440. Such design not only allows the fourth wiring layer 440 to be electrically connected to the third light-emitting element 10c, but also prevents poor electrical contact between the fourth wiring layer 440 and the third light-emitting element 10c caused by cracks formed in the second electrode pad 42 of the third light-emitting element 10c at the top edge of the sidewall that defines the corresponding second opening (OP2) of the insulating layer 30.

In one embodiment, as shown in FIG. 2, a minimum distance (L1) formed between the first wiring layer 410 and the second wiring layer 420 on the first light-emitting element 10a ranges from 1 μm to 50 μm. If the minimum distance (L1) is too small, a short circuit may occur between the first wiring layer 410 and the second wiring layer 420. Similarly, a minimum distance (L1) between the first wiring layer 410 and the third wiring layer 430 on the second light-emitting element 10b also ranges from 1 μm to 50 μm, and a minimum distance (L1) between the first wiring layer 410 and the fourth wiring layer 440 on the third light-emitting element 10c ranges from 1 μm to 50 μm.

In one embodiment, a minimum width (W) of the wiring unit 400 ranges from 1 μm to 50 μm.

Referring to FIG. 3 again, the passivation layer 500 is disposed on a surface of the wiring unit 400 away from the transparent layer 100 and surrounds a periphery of the wiring unit 400. The passivation layer 500 includes grooves 500a that are formed on the wiring unit 400 to expose the wiring unit 400. The pixel unit 10 may be mounted on the circuit substrate through a bonding material, e.g., a solder material, which may extend into the grooves 500a to be connected to the wiring unit 400.

The passivation layer 500 may be made of a material such as epoxy resin, polysiloxane or a photoresist, which may prevent the wiring unit 400 from oxidization and may electrically isolate the different wiring layers so as to avoid leakage or failure of the pixel unit 10.

Referring to FIG. 3 again, in this embodiment, the pixel unit 10 further includes a bonding layer 200 that is disposed between the transparent layer 100 and the light-emitting elements, so that the light-emitting elements may be bonded to the transparent layer 100 through the bonding layer 200. The bonding layer 200 may completely cover the transparent layer 100, but is not limited thereto, and may also be only located directly beneath the light-emitting elements (i.e., only cover a portion of the transparent layer 100 directly beneath the light-emitting elements), so that the light-emitting elements may be bonded to the transparent layer 100 through the bonding layer 200. Since different light-emitting elements generally have different thicknesses, by virtue of disposing the bonding layer 200 between the transparent layer 100 and the light-emitting elements, differences in height among the light-emitting elements may be reduced, so that light emitted from sidewalls of the light-emitting elements may be absorbed by the filling layer 300 as much as possible, so as to improve the contrast of the pixel unit 10. A thickness of the bonding layer 200 may range from 1 μm to 15 μm or from 3 μm to 10 μm.

Referring to FIG. 3 again, in this embodiment, the pixel unit 10 further includes a protection electrode 600. When the material for forming the wiring unit 400 is easily oxidized, for example, when the wiring unit 400 is made of Cu, a portion of the wiring unit 400 exposed from the grooves 500a of the passivation layer 500 is easily oxidized. The protection electrode 600 may be formed in the grooves 500a of the passivation layer 500 so as to protect the portion of the wiring unit 400 that is exposed from the grooves 500a of the passivation layer 500. In this embodiments, a plurality of the protection electrodes 600 may be formed on portions of the wiring layers that are exposed and be electrically connected to the wiring layers.

In one embodiment, the protection electrode 600 may be made of nickel, gold, platinum, chromium, tin, palladium, or combinations thereof. A thickness of the protection electrode 600 ranges from 1 μm to 6 μm. For example, the thickness of the protection electrode 600 may be 2 μm, 3 μm, 4 μm, 5 μm, etc.

In one embodiment, the protection electrode 600 includes a first layer structure and a second layer structure. A thickness of the first layer structure is greater than a thickness of the second layer structure. In an embodiment, the first layer structure may be a nickel layer, and the second layer structure may be a gold layer. The thickness of the first layer structure may range from 2 μm to 5 μm, and the thickness of the second layer structure may range from 20 Å to 50 Å. Such ratio of the thickness of the first layer structure to the thickness of the second layer structure enables better flatness. In one embodiment, the wiring unit 400 includes Cu. When a top portion of the wiring unit 400 includes Cu, a part of the top portion of the wiring unit 400 is in contact with the passivation layer 500, and another part of the top portion of the wiring unit 400 is exposed from the groove 500a of the passivation layer 500 and is in contact with the protection electrode 600, thereby being protected by the protection electrode 600 from oxidation.

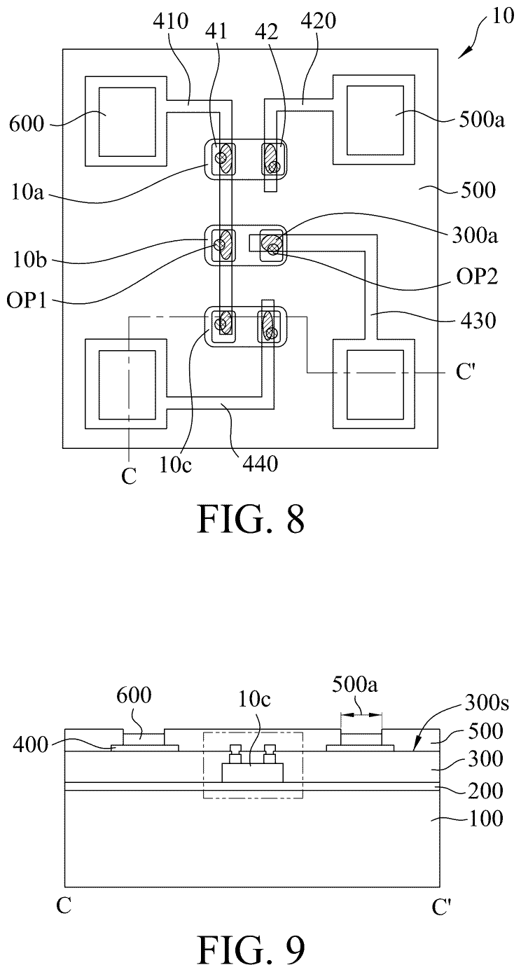

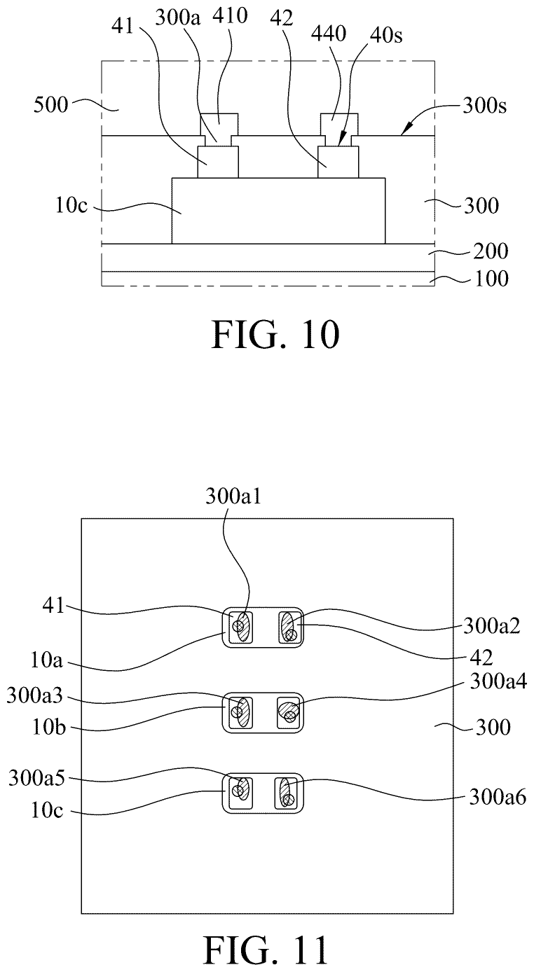

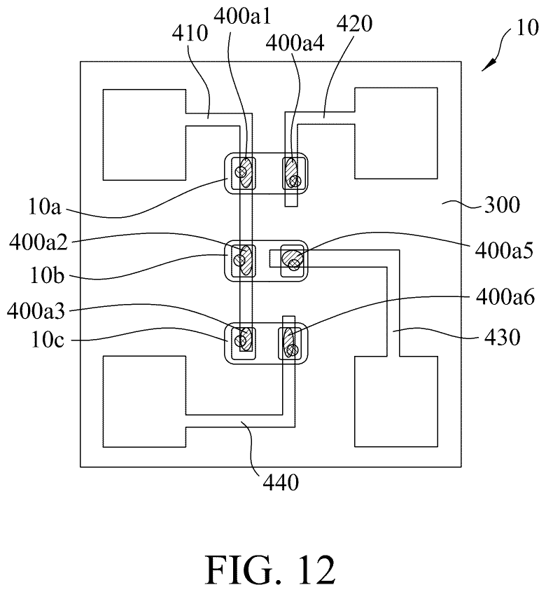

FIG. 8 is a schematic top view of the pixel unit 10 according to yet another embodiment of the present disclosure, FIG. 9 is a schematic cross-sectional view taken along line C-C′ of FIG. 8, FIG. 10 is a partially enlarged schematic view of FIG. 9, FIG. 11 is a schematic view illustrating the filling layer 300 according to an embodiment of the present disclosure, and FIG. 12 is a schematic view illustrating the wiring unit 400 according to an embodiment of the present disclosure.

Referring to FIGS. 8, 9 and 10, in this embodiment, the pixel unit 10 has a structure that is substantially similar to that of the previous embodiment, except for the positional relationship between the filling layer 300 and the light-emitting elements.

In this embodiment, referring to FIG. 10 with the third light-emitting element 10c being an example, the surface 300s of the filling layer 300 away from the transparent layer 100 is higher than the surface 40s of each of the electrode pads (i.e., the first and second electrode pads 41, 42) of the third light-emitting element 10c that is the farthest away from the transparent layer 100. That is to say, the filling layer 300 is formed on and in contact with a part of the surface 40s of each the first and second electrode pads 41, 42 of the third light-emitting element 10c. The filling layer 300 includes the opening portions 300a that expose the surface 40s of each the first and second electrode pads 41, 42. The wiring unit 400 is disposed on the filling layer 300 and extends into the opening portions 300a of the filling layer 300 to be electrically connected to the third light-emitting element 10c.

As shown in FIG. 10, at least one of the opening portions 300a of the filling layer 300 exposes the contact region of a corresponding one of the first and second electrode pads 41, 42 of the third light-emitting element 10c, and the wiring unit 400 extends into the opening portion 300a to be in contact with the contact region of the corresponding one of the first and second electrode pads 41, 42 of the third light-emitting element 10c. Such design not only enables the wiring unit 400 to be electrically connected to the third light-emitting element 10c, but also prevents poor electrical contact between the wiring unit 400 and the third light-emitting element 10c caused by cracks formed in the first and second electrode pads 41, 42 of the third light-emitting element 10c at the top edges of the sidewalls that define the first and second openings (OP1, OP2) of the insulating layer 30, thereby improving the reliability of the pixel unit 10. In the event of poor electrical connection occurring at the first contact region 41a of the first electrode pad 41 in the first opening (OP1) of the insulating layer 30 and at the second contact region 42a of the second electrode pad 42 in the second opening (OP2) of the insulating layer 30, electrical connection is instead established between the wiring unit 400 and regions of the first and second electrode pads 41, 42 outside the first and second contact regions 41a, 42a, consequently the pixel unit 10 may experience undesired open or short-circuits. In an embodiment, a contact area between the wiring unit 400 and the contact region of each of the first and second electrode pads 41, 42 of each light-emitting element occupies at least 50% of a total area of the contact region of each of the first and second electrode pads 41, 42 of each light-emitting element.

In one embodiment, as shown in FIG. 11, the opening portions 300a of the filling layer 300 includes a first opening portion 300a1, a second opening portion 300a2, a third opening portion 300a3, a fourth opening portion 300a4, a fifth opening portion 300a5, and a sixth opening portion 300a6. The first opening portion 300a1 at least partially exposes the first electrode pad 41 of the first light-emitting element 10a, the second opening portion 300a2 at least partially exposes the second electrode pad 42 of the first light-emitting element 10a, the third opening portion 300a3 at least partially exposes the first electrode pad 41 of the second light-emitting element 10b, the fourth opening portion 300a4 at least partially exposes the second electrode pad 42 of the second light-emitting element 10b, the fifth opening portion 300a5 at least partially exposes the first electrode pad 41 of the third light-emitting element 10c, and the sixth opening portion 300a6 at least partially exposes the second electrode pad 42 of the third light-emitting element 10c.

In one embodiment, the first opening portion 300a1 exposes at least a portion of the first contact region 41a of the first electrode pad 41 of the first light-emitting element 10a, the second opening portion 300a2 exposes at least a portion of the second contact region 42a of the second electrode pad 42 of the first light-emitting element 10a, the third opening portion 300a3 exposes at least a portion of the first contact region 41a of the first electrode pad 41 of the second light-emitting element 10b, the fourth opening portion 300a4 exposes at least a portion of the second contact region 42a of the second electrode pad 42 of the second light-emitting element 10b, the fifth opening portion 300a5 exposes at least a portion of the first contact region 41a of the first electrode pad 41 of the third light-emitting element 10c, and the sixth opening portion 300a6 exposes at least a portion of the second contact region 42a of the second electrode pad 42 of the third light-emitting element 10c.

A projection of at least one of the opening portions 300a of the filling layer 300 on the imaginary plane at least partially overlaps a projection of a corresponding one of the openings of the insulating layer 30 of at least one of the light-emitting elements on the imaginary plane. As shown in FIG. 11, a projection of the first opening portion 300a1 of the filling layer 300 on the imaginary plane partially overlaps a projection of the first opening (OP1) of the insulating layer 30 of the first light-emitting element 10a on the imaginary plane. A projection of the second opening portion 300a2 of the filling layer 300 on the imaginary plane partially overlaps a projection of the second opening (OP2) of the insulating layer 30 of the first light-emitting element 10a on the imaginary plane. A projection of the third opening portion 300a3 of the filling layer 300 on the imaginary plane partially overlaps a projection of the first opening (OP1) of the insulating layer 30 of the second light-emitting element 10b on the imaginary plane. A projection of the fourth opening portion 300a4 of the filling layer 300 on the imaginary plane partially overlaps a projection of the second opening (OP2) of the insulating layer 30 of the second light-emitting element 10b on the imaginary plane. A projection of the fifth opening portion 300a5 of the filling layer 300 on the imaginary plane partially overlaps a projection of the first opening (OP1) of the insulating layer 30 of the third light-emitting element 10c on the imaginary plane. A projection of the sixth opening portion 300a6 of the filling layer 300 on the imaginary plane partially overlaps a projection of the second opening (OP2) of the insulating layer 30 of the third light-emitting element 10c on the imaginary plane.

In one embodiment, as shown in FIG. 11, an area of the projection of at least one of the opening portions 300a of the filling layer 300 on the imaginary plane is greater than an area of the projection of a corresponding one of the first opening (OP1) and the second opening (OP2) of at least one of the light-emitting elements on the imaginary plane. In one embodiment, referring to FIG. 12, the wiring unit 400 is disposed on the filling layer 300. The first wiring layer 410 is electrically connected to the first light-emitting element 10a, the second light-emitting element 10b, and the third light-emitting element 10c through the first opening portion 300a1, the third opening portion 300a3, and the fifth opening portion 300a5 of the filling layer 300, respectively. The first wiring layer 410 has a first portion 400a1 which passes through the first opening portion 300a1 to be in contact with the first electrode pad 41 of the first light-emitting element 10a, the second wiring layer 420 has a second portion 400a2 which passes through the third opening portion 300a3 of the filling layer 300 to be in contact with the first electrode pad 41 of the second light-emitting element 10b, and the third wiring layer 430 has a third portion 400a3 which passes through the fifth opening portion 300a5 of the filling layer 300 to be in contact with the first electrode pad 41 of the third light-emitting element 10c. The first portion 400a1 of the first wiring layer 410 is in partial contact with the first contact region 41a of the first electrode pad 41 of the first light-emitting element 10a, the second portion 400a2 of the first wiring layer 410 is in partial contact with the first contact region 41a of the first electrode pad 41 of the second light-emitting element 10b, and the third portion 400a3 of the first wiring layer 410 is in partial contact with the first contact region 41a of the first electrode pad 41 of the third light-emitting element 10c. The second wiring layer 420 has a fourth portion 400a4 which passes through the second opening portion 300a2 of the filling layer 300 to be in contact with the second electrode pad 42 of the first light-emitting element 10a. The fourth portion 400a4 of the second wiring layer 420 is in partial contact with the second contact region 42a of the second electrode pad 42 of the first light-emitting element 10a. The third wiring layer 430 has a fifth portion 400a5 which passes through the fourth opening portion 300a4 of the filling layer 300 to be in contact with the second electrode pad 42 of the second light-emitting element 10b. The fifth portion 400a5 of the third wiring layer 430 is in partial contact with the second contact region 42a of the second electrode pad 42 of the second light-emitting element 10b. The fourth wiring layer 440 has a sixth portion 400a6 which passes through the sixth opening portion 300a6 of the filling layer 300 to be in contact with the second electrode pad 42 of the third light-emitting element 10c. The sixth portion 400a6 of the fourth wiring layer 440 is in partial contact with the second contact region 42a of the second electrode pad 42 of the third light-emitting element 10c. Such design not only allows the wiring unit 400 to be electrically connected to the first, second, and third light-emitting elements 10a, 10b, 10c, but also prevents poor electrical contact between the wiring unit 400 and at least one of the first, second, and third light-emitting elements 10a, 10b, 10c caused by cracks formed in at least one of the first and second electrode pads 41, 42 of at least one of the first, second, and third light-emitting elements 10a, 10b, 10c at the top edges of the sidewalls that define the first and second openings (OP1, OP2) of the insulating layer 30, thereby improving the reliability of the pixel unit 10. In the event of poor electrical connection occurring at the first contact region 41a of the first electrode pad 41 in the first opening (OP1) of the insulating layer 30 and at the second contact region 42a of the second electrode pad 42 in the second opening (OP2) of the insulating layer 30, electrical connection is instead established between the wiring unit 400 and regions of the first and second electrode pads 41, 42 outside the first and second contact regions 41a, 42a, consequently the pixel unit 10 may experience undesired open or short-circuits.

A projection of the first portion 400a1 of the first wiring layer 410 on the imaginary plane overlaps a projection of the first opening portion 300a1 of the filling layer 300 on the imaginary plane, a projection of the second portion 400a2 of the first wiring layer 410 on the imaginary plane overlaps a projection of the third opening portion 300a3 of the filling layer 300 on the imaginary plane, a projection of the third portion 400a3 of the first wiring layer 410 on the imaginary plane overlaps a projection of the fifth opening portion 300a5 of the filling layer 300 on the imaginary plane, a projection of the fourth portion 400a4 of the second wiring layer 420 on the imaginary plane overlaps a projection of the second opening portion 300a2 of the filling layer 300 on the imaginary plane, a projection of the fifth portion 400a5 of the third wiring layer 430 on the imaginary plane overlaps a projection of the fourth opening portion 300a4 of the filling layer 300 on the imaginary plane, and a projection of the sixth portion 400a6 of the fourth wiring layer 440 on the imaginary plane partially overlaps a projection of the sixth opening portion 300a6 of the filling layer 300 on the imaginary plane.

In one embodiment, each of the opening portions 300a of the filling layer 300 has an elliptical shape or a circular shape.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A pixel unit, comprising:
light-emitting elements that are spaced apart from each other, each of said light-emitting elements including
a semiconductor stacked structure which includes a first semiconductor layer, an active layer, and a second semiconductor layer sequentially disposed in such order in a laminating direction,
an insulating layer which is disposed on said semiconductor stacked structure and which has openings, said openings including a first opening and a second opening, and
electrode pads which include a first electrode pad and a second electrode pad, said first electrode pad being electrically connected to said first semiconductor layer through said first opening, said second electrode pad being electrically connected to said second semiconductor layer through said second opening; and
a wiring unit that is disposed on and electrically connected to said light-emitting elements,
wherein each of said electrode pads of each of said light-emitting elements includes a contact region that extends into a respective one of said openings of said insulating layer, and said wiring unit is at least in partial contact with said contact region of each of said electrode pads of each of said light-emitting elements.

2. The pixel unit as claimed in claim 1, further comprising a transparent layer on which said light-emitting elements are disposed, for each of said light-emitting elements, said contact regions of said electrode pads including a first contact region and a second contact region, said first electrode pad having said first contact region that extends into said first opening of said insulating layer, said second electrode pad having said second contact region that extends into said second opening of said insulating layer.

3. The pixel unit as claimed in claim 2, further comprising a filling layer that is disposed among said light-emitting elements, a surface of said filling layer away from said transparent layer is lower than a surface of each of said electrode pads of each of said light-emitting elements that is farthest away from said transparent layer, or said surface of said filling layer away from said transparent layer is higher than said surface of each of said electrode pads of each of said light-emitting element that is the farthest away from said transparent layer.

4. The pixel unit as claimed in claim 3, wherein said filling layer includes opening portions, at least one of said opening portions of said filling layer exposes said contact region of a corresponding one of said electrode pads.

5. The pixel unit as claimed in claim 4, wherein said wiring unit is in partial contact with said contact region of said corresponding one of said electrode pads through said at least one of said opening portions of said filling layer.

6. The pixel unit as claimed in claim 4, wherein an area of a projection of at least one of said opening portions of said filling layer on an imaginary plane perpendicular to the laminating direction is greater than an area of a projection of a corresponding one of said openings of said insulating layer of at least one of said light-emitting elements on the imaginary plane.

7. The pixel unit as claimed in claim 4, wherein a projection of at least one of said opening portions of said filling layer on an imaginary plane perpendicular to the laminating direction at least partially overlaps a projection of a corresponding one of said openings of said insulating layer of at least one of said light-emitting elements on the imaginary plane.

8. The pixel unit according to claim 4, wherein said wiring unit includes a first wiring layer, a second wiring layer, a third wiring layer and a fourth wiring layer, said light-emitting elements including a first light-emitting element, a second light-emitting element and a third light-emitting element, each of said first light-emitting element, said second light-emitting element and said third light-emitting element including said first electrode pad and said second electrode pad, said first wiring layer being electrically connected to said first electrode pad of each of said first light-emitting element, said second light-emitting element and said third light-emitting element, said second wiring layer being electrically connected to said second electrode pad of said first light-emitting element, said third wiring layer being electrically connected to said second electrode pad of said second light-emitting element, said fourth wiring layer being electrically connected to said second electrode pad of said third light-emitting element.

9. The pixel unit as claimed in claim 8, wherein said opening portions of said filling layer includes a first opening portion, a second opening portion, a third opening portion, a fourth opening portion, a fifth opening portion and a sixth opening portion, said first opening portion at least partially exposes said first contact region of said first electrode pad of said first light-emitting element, said second opening portion at least partially exposes said second contact region of said second electrode pad of said first light-emitting element, said third opening portion at least partially exposes said first contact region of said first electrode pad of said second light-emitting element, said fourth opening portion at least partially exposes said second contact region of said second electrode pad of said second light-emitting element, said fifth opening portion at least partially exposes said first contact region of said first electrode pad of said third light-emitting element, and said sixth opening portion at least partially exposes said second contact region of said second electrode pad of said third light-emitting element.

10. The pixel unit as claimed in claim 9, wherein said first wiring layer is in partial contact with said first contact region of said first electrode pad of each of said first light-emitting element, said second light-emitting element and said third light-emitting element through said first opening portion, said third opening portion and said fifth opening portion of said filling layer, respectively, said second wiring layer is in partial contact with said second contact region of said second electrode pad of said first light-emitting element through said second opening portion of said filling layer, said third wiring layer is in partial contact with said second contact region of said second electrode pad of said second light-emitting element through said fourth opening portion of said filling layer, and said fourth wiring layer is in partial contact with said second contact region of said second electrode pad of said third light-emitting element through said sixth opening portion of said filling layer.

11. The pixel unit as claimed in claim 4, wherein each of said opening portions of said filling layer has an elliptical shape or a circular shape.

12. The pixel unit as claimed in claim 3, wherein said surface of each of said electrode pads of said light-emitting elements is free of said filling layer.

13. The pixel unit as claimed in claim 12, wherein a projection of said contact region of at least one of said electrode pads of at least one of said light-emitting elements on an imaginary plane perpendicular to the laminating direction partially overlaps a projection of said wiring unit on said imaginary plane.

14. The pixel unit as claimed in claim 12, wherein a projection of said contact region of at least one of said electrode pads of at least one of said light-emitting elements on an imaginary plane perpendicular to the laminating direction falls within a projection of said wiring unit on said imaginary plane.

15. The pixel unit as claimed in claim 12, wherein a projection of at least one of said electrode pads of said light-emitting elements on an imaginary plane perpendicular to the laminating direction falls within a projection of said wiring unit (400) on the imaginary plane.

16. The pixel unit as claimed in claim 1, wherein an entirety of said contact region of each of said electrode pads of each of said light-emitting elements is in contact with said wiring unit.

17. The pixel unit as claimed in claim 8, wherein a minimum distance is formed between said first wiring layer and said second wiring layer, a minimum distance is formed between said first wiring layer and said third wiring layer, a minimum distance is formed between said first wiring layer and said fourth wiring layer, and each of said minimum distances ranges from 1 μm to 50 μm.

18. The pixel unit as claimed in claim 1, wherein a minimum width of said wiring unit ranges from 1 μm to 50 μm.

19. The pixel unit as claimed in claim 1, wherein a contact area between said wiring unit and said contact region of each of said electrode pads of each of said light-emitting elements occupies at least 50% of a total area of said contact region of each of said electrode pads of each of said light-emitting elements.

20. A display device, comprising:
a panel substrate; and
a plurality of pixel modules that are disposed on said panel substrate, each of said pixel modules including said pixel unit as claimed in claim 1.
